(19) United States
(12) Patent Application Publication
(10) Pub. No.: US 2026/0231617 A1
(43) Pub. Date: Aug. 6, 2026

(54) DISPLAY PANEL AND PREPARATION METHOD THEREOF

(71) Applicant: Guangzhou China Star Optoelectronics Semiconductor Display Technology Co., LTd., Guangzhou (CN)

(72) Inventors: Jun ZHAO, Guangzhou (CN); Xiaolin YAN, Guangzhou (CN); Bin ZHAO, Guangzhou (CN); Weiran CAO, Guangzhou (CN); Jia TANG, Guangzhou (CN); Shuaiyi WANG, Guangzhou (CN)

(73) Assignee: Guangzhou China Star Optoelectronics Semiconductor Display Technology Co., LTd., Guangzhou (CN)

(21) Appl. No.: 19/224,790

(22) Filed: May 31, 2025

(30) Foreign Application Priority Data
Jan. 24, 2025 (CN) 202510122918.1

(51) Int. Cl. H10K 59/122; H10K 59/12

(52) U.S. Cl. CPC H10K 59/122; H10K 59/1201

(57) ABSTRACT

A display panel and a preparation method thereof. One photomask is used to form a patterned photoresist layer. The photoresist layer is used as a mask to form a patterned first inorganic pixel definition layer and a patterned second inorganic pixel definition layer. Based on the fact that both a baking temperature and a baking time for preparing the photoresist layer by using a conventional method are lower than a heating temperature and a heating time in a thermal process for preparing an organic pixel definition layer, in embodiments of the present disclosure, the influence of the thermal process on the thin film transistor can be reduced, thereby reducing the risk of negative bias of the thin film transistor and the number of the used photomasks.

### CROSS-REFERENCE TO RELATED APPLICATION

The present disclosure claims priority to and the benefit of Chinese Patent Application No. 202510122918.1, filed on January 24, 2025, the disclosure of which is incorporated herein by reference in its entirety.

### TECHNICAL FIELD

The present disclosure relates to the field of display, and more particularly, to a display panel and a preparation method thereof.

### BACKGROUND

In an existing OLED display panel, a pixel definition layer is usually provided after an oxide thin film transistor is formed. For a linear pixel definition structure layer, it includes two organic pixel definition layers. One organic pixel definition layer includes first retaining walls extending in a transverse direction. The other organic pixel definition layer includes second retaining walls extending in a longitudinal direction. The first retaining walls and the second retaining walls intersect to form pixel openings for printing ink materials.

In a process of studying and practicing the prior art, inventors of the present disclosure find that a long-term high temperature environment can cause negative bias of oxide thin film transistor. The formation of the first organic pixel definition layer and the second organic pixel definition layer together requires two thermal processes, which easily lead to the risk of negative bias of the oxide thin film transistor.

### SUMMARY

The embodiments of the present disclosure provide a display panel and a preparation method thereof, which can reduce the risk of negative bias of a thin film transistor and the number of the used photomasks.

The embodiments of the present disclosure provide a method of preparing a display panel, which includes steps as follows:

forming a thin film transistor structure layer, a plurality of first electrodes, a first inorganic layer, and a second inorganic layer sequentially on a substrate, wherein the first inorganic layer and the second inorganic layer are stacked to form an inorganic stacked structure;

forming a patterned photoresist layer on one side of the second inorganic layer away from the substrate; wherein the photoresist layer includes a plurality of first photoresist strips and a plurality of second photoresist strips, the plurality of first photoresist strips and the plurality of second photoresist strips are cross-connected to form a plurality of openings, a thickness of each of the plurality of first photoresist strips is less than a thickness of each of the plurality of second photoresist strips, each of the plurality of openings is disposed corresponding to each of the plurality of first electrodes, and a pattern of each of the plurality of openings in a top view is within an area of each of the plurality of first electrodes;

etching the inorganic stacked structure by using the photoresist layer as a mask; and ashing the photoresist layer to remove the plurality of first photoresist strips, thin the plurality of second photoresist strips, and form a plurality of grooves on one side of the inorganic stacked structure away from the substrate; and

etching the inorganic stacked structure by using the thinned plurality of second photoresist strips as a mask while ashing to remove the plurality of second photoresist strips, so that the inorganic stacked structure forms a stacked first inorganic pixel definition layer and a second inorganic pixel definition layer; wherein the first inorganic pixel definition layer includes a plurality of first pixel definition portions and a plurality of second pixel definition portions, and the plurality of first pixel definition portions and the plurality of second pixel definition portions are cross-connected to form a plurality of pixel openings exposing the plurality of first electrodes; the second inorganic pixel definition layer includes a plurality of third pixel definition portions, an extension direction of the plurality of third pixel definition portions is consistent with an extension direction of the plurality of first pixel definition portions, and each of the plurality of third pixel definition portions is correspondingly disposed on one side of each of the plurality of first pixel definition portions away from the substrate.

Optionally, in some embodiments of the present disclosure, said “etching the inorganic stacked structure by using the thinned plurality of second photoresist strips as a mask while ashing to remove the plurality of second photoresist strips” includes:

etching the inorganic stack structure, so that the plurality of pixel openings exposing the plurality of first electrodes are formed in areas of the inorganic stack structure corresponding to the plurality of grooves; wherein the second inorganic layer is removed and the first inorganic layer is remained in areas of the inorganic stack structure corresponding to the plurality of first photoresist strips, and both the first inorganic layer and the second inorganic layer are remained in areas of the inorganic stack structure corresponding to the plurality of second photoresist strips; and wherein the patterned first inorganic layer forms a first inorganic pixel definition layer, and the patterned second inorganic layer forms a second inorganic pixel definition layer.

Optionally, in some embodiments of the present disclosure, a rate of etching the inorganic stacked structure in said “etching the inorganic stacked structure by using the photoresist layer as a mask; and ashing the photoresist layer” is a first rate; and

a rate of etching the inorganic stacked structure in said “etching the inorganic stacked structure by using the thinned plurality of second photoresist strips as a mask while ashing to remove the plurality of second photoresist strips” is a second rate;

wherein the second rate is less than the first rate.

Optionally, in some embodiments of the present disclosure, the thickness of each of the plurality of first photoresist strips is between 2/3 and 4/5 of the thickness of each of the plurality of second photoresist strips; and

in said “etching the inorganic stacked structure by using the photoresist layer as a mask; and ashing the photoresist layer”, a thickness ratio of each of the plurality of first photoresist strips to the second inorganic layer is equal to an etching selectivity ratio of each of the plurality of first photoresist strips to the second inorganic layer.

Optionally, in some embodiments of the present disclosure, in said “etching the inorganic stacked structure by using the thinned plurality of second photoresist strips as a mask while ashing to remove the plurality of second photoresist strips”, a thickness of each of the thinned plurality of second photoresist strips is less than or equal to a thickness of the first inorganic layer, and a rate of etching each of the plurality of second photoresist strips is less than a rate of etching the first inorganic layer.

Optionally, in some embodiments of the present disclosure, in said “forming a patterned photoresist layer”, a drying temperature of the photoresist layer is between 60 °C and 150 °C, and a drying time of the photoresist layer is less than 25 minutes.

Optionally, in some embodiments of the present disclosure, the first inorganic layer and the second inorganic layer are formed by chemical vapor deposition, and a temperature of the ambient temperature at which the photoresist is subjected to ashing is between 15 °C and 35 °C.

Optionally, in some embodiments of the present disclosure, said “forming a patterned photoresist layer on one side of the second inorganic layer away from the substrate” includes:

forming a first pattern of the photoresist layer on one side of the second inorganic layer away from the substrate; wherein the first pattern of the photoresist layer includes a first initial photoresist strip, a second initial photoresist strip and a third initial photoresist portion, the first pattern of the photoresist layer is further provided with an initial opening exposing the inorganic stacked structure, the third initial photoresist portion is located in a display area and is connected with the first initial photoresist strip and the second initial photoresist strip around it, the initial opening is located in a pixel redundancy area and the first initial photoresist strip and the second initial photoresist strip being disposed around the initial opening, and each of the third initial photoresist portion and the initial opening respectively corresponds to one of the plurality of first electrodes;

forming a second pattern of the photoresist layer by ashing the first pattern of the photoresist layer and removing the third initial photoresist strip while etching the inorganic stacked structure by using the first pattern of the photoresist layer as a mask; wherein the second pattern of the photoresist layer includes a plurality of first photoresist strips and a plurality of second photoresist strips, the plurality of first photoresist strips and the plurality of second photoresist strips are cross-connected to form a plurality of openings, a thickness of each of the plurality of first photoresist strips is less than a thickness of each of the plurality of second photoresist strips; in the display area, each of the plurality of openings corresponds to each of the plurality of first electrodes, the pattern of each of the plurality of openings in a top view is within the area of each of the plurality of first electrodes; and in the pixel redundancy area, the inorganic stacked structure is formed with a redundant recessed groove in an area corresponding to the initial opening;

said "etching the inorganic stacked structure by using the photorcsist layer as a mask; and ashing the photorcsist layer" further includes forming a redundant opening exposing the plurality of first electrodes in an area of the inorganic stack structure corresponding to the redundant recessed groove in the pixel redundancy area; and

said “etching the inorganic stacked structure by using the thinned plurality of second photoresist strips as a mask while ashing to remove the plurality of second photoresist strips” further includes extending the redundant opening in a direction towarding the plurality of first electrodes to penetrate through at least a part of each of the plurality of first electrodes in the pixel redundancy area.

Accordingly, embodiments of the present disclosure further provide a display panel which includes:

a substrate;

a thin film transistor structure layer disposed on the substrate, wherein the thin film transistor structure layer includes a thin film transistor;

a plurality of first electrodes disposed on one side of the thin film transistor structure layer away from the substrate;

a first inorganic pixel definition layer disposed on one side of the thin film transistor structure layer away from the substrate, wherein the first inorganic pixel definition layer includes a plurality of first pixel definition portions and a plurality of second pixel definition portions, and the plurality of first pixel definition portions and the plurality of second pixel definition portions are cross-connected to form a plurality of pixel openings exposing the plurality of first electrodes; and

a second inorganic pixel definition layer disposed on one side of the first inorganic pixel definition layer away from the substrate, wherein the second inorganic pixel definition layer includes a plurality of third pixel definition portions, an extension direction of the plurality of third pixel definition portions is consistent with an extension direction of the plurality of first pixel definition portions, and each of the plurality of third pixel definition portions is correspondingly disposed on one side of each of the plurality of first pixel definition portions away from the substrate.

Optionally, in some embodiments of the present disclosure, a thickness of each of the plurality of third pixel defining portions is greater than a thickness of the first inorganic pixel defining layer.

Optionally, in some embodiments of the present disclosure, the display panel includes a display area and a pixel redundancy area disposed on at least one side of the display area, and the first inorganic pixel definition layer and the second inorganic pixel definition layer are disposed in the display area and the pixel redundancy area; the plurality of pixel openings are disposed in the display area, the first inorganic pixel defining layer is further provided with a redundant opening, and the redundant opening is disposed in the pixel redundancy area and penetrates through at least a part of each of the plurality of first electrodes.

According to the display panel and the preparation method thereof provided in the embodiments of the present disclosure, one photomask is used to form a patterned photoresist layer. The photoresist layer is used as a mask to form a patterned first inorganic pixel definition layer and a patterned second inorganic pixel definition layer. Based on the fact that both a baking temperature and a baking time for preparing the photoresist layer by using a conventional method are lower than a heating temperature and a heating time in a thermal process for preparing an organic pixel definition layer, in embodiments of the present disclosure, the influence of the thermal process on the thin film transistor can be reduced, thereby reducing the risk of negative bias of the thin film transistor and the number of the used photomasks.

### BRIEF DESCRIPTION OF THE DRAWINGS

FIG. 1 is a schematic flow diagram of a method of preparing a display panel according to embodiments of the present disclosure.

FIG. 2 is a schematic diagram of step B01 of a method of preparing a display panel according to embodiments of the present disclosure.

FIG. 3 is a schematic diagram of step B02 of a method of preparing a display panel according to embodiments of the present disclosure.

FIG. 4 is a schematic diagram of step B03 of a method of preparing a display panel according to embodiments of the present disclosure.

FIG. 5 is a schematic diagram of step B04 of a method of preparing a display panel according to embodiments of the present disclosure.

FIG. 6 is a schematic diagram of step B021 of another method of preparing a display panel according to embodiments of the present disclosure.

FIG. 7 is a schematic diagram of step B021 of another method of preparing a display panel according to embodiments of the present disclosure.

FIG. 8 is a schematic diagram of step B021 of another method of preparing a display panel according to embodiments of the present disclosure.

FIG. 9 is a schematic diagram of step B021 of another method of preparing a display panel according to embodiments of the present disclosure.

FIG. 10 is a top plan view of a display panel according to embodiments of the present disclosure.

FIG. 11 is a cross-sectional structural diagram along line MN in FIG. 10.

FIG. 12 is another schematic structural diagram of a display panel according to embodiments of the present disclosure.

### DETAILED DESCRIPTION

Hereinafter, technical solution in embodiments of the present application will be clearly and completely described with reference to the accompanying drawings in embodiments of the present application. Apparently, the described embodiments are part of, but not all of, the embodiments of the present application. All the other embodiments, obtained by a person with ordinary skill in the art on the basis of the embodiments in the present application without expenditure of creative labor, belong to the protection scope of the present application. In addition, it should be understood that the specific embodiments described herein are intended only to illustrate and explain the present application and are not intended to limit the present application. In the present application, in the absence of contrary description, directional words such as "up" and "down" generally refer to the up and down in the actual use or working state of a device, and specifically the drawing direction in the accompanying drawings. While "inside" and "outside" are for profile of the device. The terms "first", "second" and "third" are merely intended to be used as labels, rather than to impose numerical requirements or establish a sequence.

Embodiments of the present disclosure provide a display panel and a preparation method thereof, which are described in detail below. It should be noted that the description order of the following embodiments is not intended to limit the preferred order of the embodiments.

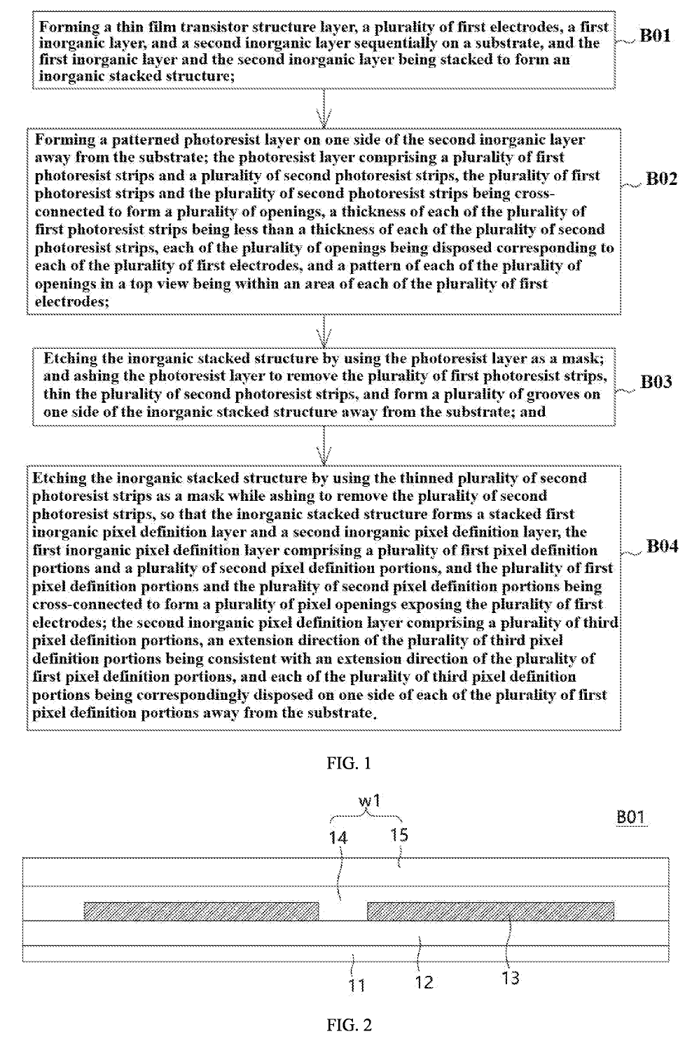

Referring to FIG. 1, embodiments of the present disclosure provide a method of preparing a display panel, which includes steps as follows:

step B01, forming a thin film transistor structure layer, a plurality of first electrodes, a first inorganic layer, and a second inorganic layer sequentially on a substrate, wherein the first inorganic layer and the second inorganic layer are stacked to form an inorganic stacked structure;

step B02, forming a patterned photoresist layer on one side of the second inorganic layer away from the substrate; wherein the photoresist layer includes a plurality of first photoresist strips and a plurality of second photoresist strips, the plurality of first photoresist strips and the plurality of second photoresist strips are cross-connected to form a plurality of openings, a thickness of each of the plurality of first photoresist strips is less than a thickness of each of the plurality of second photoresist strips, each of the plurality of openings is disposed corresponding to each of the plurality of first electrodes, and a pattern of each of the plurality of openings in a top view is within an area of each of the plurality of first electrodes;

step B03, etching the inorganic stacked structure by using the photoresist layer as a mask; and ashing the photoresist layer to remove the plurality of first photoresist strips, thin the plurality of second photoresist strips, and form a plurality of grooves on one side of the inorganic stacked structure away from the substrate; and

step B04, etching the inorganic stacked structure by using the thinned plurality of second photoresist strips as a mask while ashing to remove the plurality of second photoresist strips, so that the inorganic stacked structure forms a stacked first inorganic pixel definition layer and a second inorganic pixel definition layer; wherein the first inorganic pixel definition layer includes a plurality of first pixel definition portions and a plurality of second pixel definition portions, and the plurality of first pixel definition portions and the plurality of second pixel definition portions are cross-connected to form a plurality of pixel openings exposing the plurality of first electrodes; the second inorganic pixel definition layer includes a plurality of third pixel definition portions, an extension direction of the plurality of third pixel definition portions is consistent with an extension direction of the plurality of first pixel definition portions, and each of the plurality of third pixel definition portions is correspondingly disposed on one side of each of the plurality of first pixel definition portions away from the substrate.

It should be noted that the preparation process of an organic pixel definition layer in the related arts includes a thermal process in which a heating time is greater than or equal to 30 minutes, and a heating temperature of greater than 200 °C. Therefore, the thermal process has a great influence on the thin film transistor, which causes the stability of the thin film transistor to deteriorate, resulting in the risk of negative bias.

It can be understood that an inorganic film layer is generally formed by chemical vapor deposition, and a thermal process is not required. Therefore, the thermal process of the organic pixel definition layer can be avoided by using inorganic materials as the pixel definition layer.

According to the display panel and the preparation method thereof provided in the embodiments of the present disclosure, one photomask is used to form a patterned photoresist layer. The photoresist layer is used as a mask to form a patterned first inorganic pixel definition layer and a patterned second inorganic pixel definition layer. Based on the fact that both a baking temperature and a baking time for preparing the photoresist layer by using a conventional method are lower than a heating temperature and a heating time in a thermal process for preparing an organic pixel definition layer, in embodiments of the present disclosure, the influence of the thermal process on the thin film transistor can be reduced, thereby reducing the risk of negative bias of the thin film transistor and the number of the used photomasks.

Hereinafter, the method of preparing the display panel according to embodiments of the present application will be described.

Referring to FIG. 2, in step B01, a thin film transistor structure layer 12, a plurality of first electrodes 13, a first inorganic layer 14, and a second inorganic layer 15 are sequentially formed on a substrate 11. The first inorganic layer 14 and the second inorganic layer 15 are stacked to form an inorganic stacked structure wl.

Optionally, the substrate 11 may be a flexible substrate or a hard substrate. A material of the substrate 11 is selected from one of glass, sapphire, silicon, silicon dioxide, polyethylene, polypropylene, polystyrene, polylactic acid, polyethylene-naphthalate, polyethylene terephthalate, polyethylene naphthalate, polycarbonate, polyethersulfone, aromatic fluorotoluene containing polyarylates, polycyclic olefins, polyimide or polyurethane.

The thin film transistor structure layer 12 includes a thin film transistor, and a channel material of the thin film transistor may be a silicon semiconductor or a metal oxide semiconductor. In the display panel of embodiments of the present disclosure, the thin film transistor is a metal oxide semiconductor thin film transistor.

The thin film transistor may be a thin film transistor with a top gate, bottom gate, double gate or vertical channel architecture.

The first electrode 13 may be an anode or a cathode. In the method of preparing a display panel in embodiments of the present disclosure, it is described, for example, by taking the first electrode 13 as an anode.

Optionally, in some embodiments of the present disclosure, the first inorganic layer 14 and the second inorganic layer 15 are formed by chemical vapor deposition. Optionally, materials of the first inorganic layer 14 and the second inorganic layer 15 may be the same or different. Optionally, materials of each of the first inorganic layer 14 and the second inorganic layer 15 may be inorganic materials such as silicon oxide, silicon nitride, aluminum oxide, and zirconium oxide.

Optionally, the thickness of the first inorganic layer 14 may be between 1000 angstroms and 5500 angstroms, for example, it may be 1000 angstroms, 1500 angstroms, 2000 angstroms, 2500 angstroms, 3000 angstroms, 3500 angstroms, 4000 angstroms, 4500 angstroms, 5000 angstroms, or 5500 angstroms.

The thickness of the second inorganic layer 15 is between 5000 angstroms and 15000 angstroms, for example, it may be 5000 angstroms, 5500 angstroms, 6000 angstroms, 6500 angstroms, 7000 angstroms, 7500 angstroms, 8000 angstroms, 8500 angstroms, 9000 Angstroms, 9500 angstroms, 10000 angstroms, 10500 angstroms, 11,000 angstroms, 11500 angstroms, 12,000 angstroms, 12500 angstroms, 13,000 angstroms, 13500 angstroms, 14,000 angstroms, 14500 angstroms, or 15,000 angstroms.

The thickness of second inorganic layer 15 is greater than that of the first inorganic layer 14, so that the subsequent first inorganic pixel definition layer p1 has a less thickness, and the second inorganic pixel definition layer p2 has a greater thickness, so as to form pixel rows or pixel columns that are spaced from each other, thereby facilitating the subsequent printing of the entire rows or columns with ink.

Then, moving to step B02.

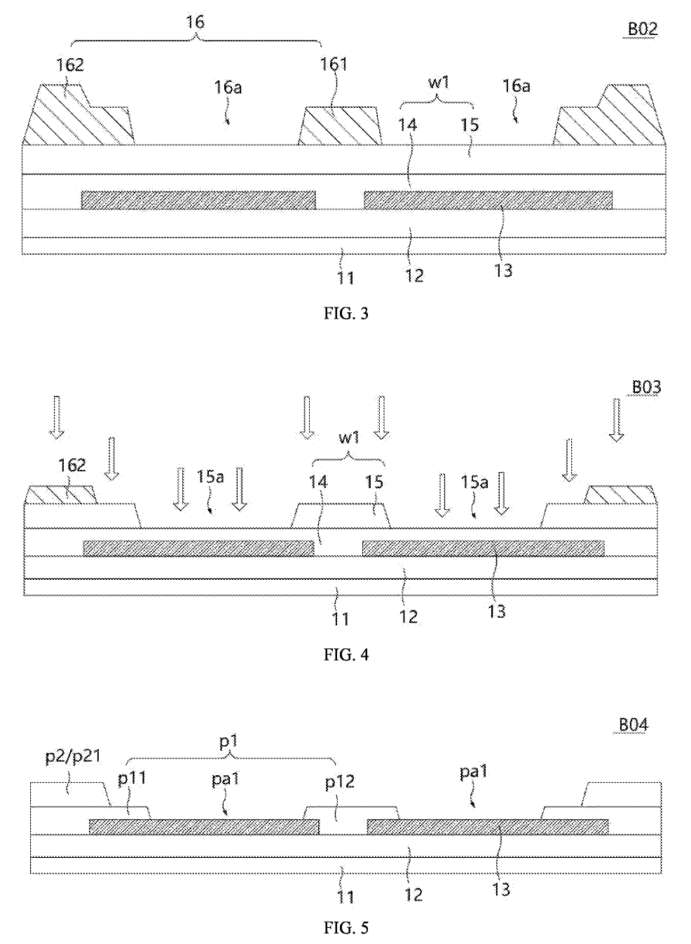

Referring to FIG. 3, in step B02, a patterned photoresist layer 16 is formed on one side of the second inorganic layer 15 away from the substrate 11. The photoresist layer 16 includes a plurality of first photoresist strips 161 and a plurality of second photoresist strips 162. The plurality of first photoresist strips 161 and the plurality of second photoresist strips 162 are cross-connected to form a plurality of openings 16a. The thickness of each of the plurality of first photoresist strips 161 is less than a thickness of each of the plurality of second photoresist strips 162. Each of the plurality of openings 16a is disposed corresponding to each of the plurality of first electrodes 13. The pattern of each of the plurality of openings 16a in a top view being within an area of each of the plurality of first electrodes 13.

Optionally, the drying temperature of the photoresist layer 16 may be between 60 °C and 150 °C. For example, it may be 60 °C, 70 °C, 80 °C, 90 °C, 100 °C, 110 °C, 120 °C, 130 °C, 140 °C, or 150 °C.

The drying time of the photoresist layer 16 is less than or equal to 25 minutes. For example, it may be 25 minutes, 20 minutes, 15 minutes, 10 minutes, 5 minutes, etc.

Based on the fact that both the drying temperature and the drying time for preparing the photoresist layer 16 are lower than the heating temperature and the heating time of the thermal process, a photomask is used to form the patterned photoresist layer 16. Further, the photoresist layer 16 is used as a mask to form the subsequent first inorganic pixel definition layer p1 and the second inorganic pixel definition layer p2. In this way, two thermal processes can be saved and one photomask can be saved, thereby reducing the number of the used photomasks and the risk of negative bias of a thin film transistor.

Then, moving to step B03.

Referring to FIG. 4, in step B03, the photoresist layer 16 is used as a mask, while the inorganic stacked structure w1 is etched, the photoresist layer 16 is subjected to ashing to remove the first photoresist strips 161, thin the second photoresist strips 162, and form grooves 15a on the side of the inorganic stacked structure w1 away from the substrate 11.

The grooves 15a are formed in areas of the openings 16a.

Optionally, a temperature of the ambient temperature at which the photoresist layer 16 is subjected to ashing is between 15 °C and 35 °C. For example, it may be 15 °C, 20 °C, 25 °C, 30 °C, or 35 °C. That is, the photoresist layer 16 can be subjected to ashing at room temperature.

Optionally, at least one etching gas selected from a fluorine-based gas, a chlorine-based gas, and an inert gas may be used to etch the photoresist layer 16 and the inorganic stacked structure w1 simultaneously.

Optionally, the fluorine-based gas may be carbon tetrafluoride, trifluoromethane, and sulfur hexafluoride. The chlorine-based gas may be chlorine gas. The inert gas may be argon.

Optionally, in step B03, a rate of etching the inorganic stacked structure w1 is the first rate. Here, the first rate may be a faster rate to quickly complete the etching of the second inorganic layer 15 and the first photoresist strip 161 and shorten the preparation time.

Optionally, in some embodiments of the present disclosure, a thickness ratio of the first photoresist strips 161 to the second inorganic layer 15 is equal to an etching selectivity ratio of the first photoresist strips 161 to the second inorganic layer 15.

For example, if the thickness ratio of the first photoresist strip 161 to the second inorganic layer 15 is 2:1, the etching selectivity ratio of the first photoresist strip 161 to the second inorganic layer 15 is also 2:1. Based on the fact that the etching selectivity ratio of the first photoresist strip 161 to the second inorganic layer 15 is also 2:1, at the same unit time, two unit volumes of the first photoresist strip 161 are etched at the same time when one unit volume of the second inorganic layer 15 is etched.

The thickness ratio is set to be consistent with the etching selectivity ratio, so that the second inorganic layer 15 is just etched through at the same time as etching of the first photoresist strip 161 is completed, thereby reducing the risk of over-etching and facilitating obtaining the etching condition of the second inorganic layer 15 according to the etching condition of the first photoresist strip 161.

Optionally, both the rate at which the photoresist layer 16 is etched and the rate at which the second inorganic layer 15 is etched are equal to the first rate. In view of this, it can be seen that the thickness of the first photoresist strip 161 is equal to the thickness of the second inorganic layer 15. Further, the second inorganic layer 15 needs to form the second inorganic pixel definition layer p2 in a subsequent step so that the pixel inks of adjacent rows or columns are separated, so the thickness of the second inorganic layer 15 is relatively thick, which means that the thickness of the first photoresist strip 161 should also be relatively thick to make it possible to penetrate through the first photoresist strip 161 and the second inorganic layer 15 simultaneously.

Therefore, the thickness of the first photoresist strip 161 is between 2/3 and 4/5 of the thickness of the second photoresist strip 162, for example, it can be 2/3, 3/4 or 4/5 of the thickness of the second photoresist strip 162.

Then, moving to step B04.

Referring to FIG. 5, in step B04, the thinned plurality of second photoresist strips is used as a mask, while the inorganic stacked structure w1 is etched, ashing is carried out to remove the second photoresist strip 162, so that the inorganic stacked structure w1 forms a stacked first inorganic pixel definition layer p1 and a second inorganic pixel definition layer p2. The first inorganic pixel definition layer p1 includes a plurality of first pixel definition portions p11 and a plurality of second pixel definition portions p12. The plurality of first pixel definition portions p11 and the plurality of second pixel definition portions p12 are cross-connected to form a plurality of pixel openings pa1 exposing the plurality of first electrodes. The second inorganic pixel definition layer p2 includes a plurality of third pixel definition portions p21. An extension direction of the plurality of third pixel definition portions p21 is consistent with an extension direction of the plurality of first pixel definition portions p11. Each of the plurality of third pixel definition portions p21 is correspondingly disposed on one side of each of the plurality of first pixel definition portions p11 away from the substrate 11.

Optionally, in step B04, the inorganic stacking structure w1 is etched, so that pixel openings pa1 exposing the first electrodes 13 are formed in areas of the inorganic stack structure w1 corresponding to the grooves 15a, the second inorganic layer 15 is removed and the first inorganic layer 14 is remained in areas of the inorganic stack structure w1 corresponding to the first photoresist strips 161, and both the first inorganic layer 14 and the second inorganic layer 15 are remained in areas of the inorganic stack structure w1 corresponding to the second photoresist strips 162. The patterned first inorganic layer 14 forms a first inorganic pixel definition layer p1 and the patterned second inorganic layer forms a second inorganic pixel definition layer p2.

Optionally, in step B04, the rate at which the inorganic stacked structure w1 is etched is a second rate. The second rate is less than the first rate.

It can be understood that by adopting a second rate less than the first rate in step B04, the risk of over-etching the first electrode 13 is reduced by adopting a lower etching rate.

Optionally, the thickness of the thinned second photoresist strip 162 is less than or equal to the thickness of the first inorganic layer 14. The rate at which the second photoresist strip 162 is etched is less than the rate at which the first inorganic layer 14 is etched.

It can be understood that, since the thickness of the thinned second photoresist strip 162 is relatively small, the effect of thinning the thickness of the photoresist layer 16 can be achieved by setting the rate at which the second photoresist strip 162 is etched less than the rate at which the first inorganic layer 14 is etched, so that a thinner second photoresist strip 162 can be used as a mask to etch the thicker first inorganic layer 14.

Then, moving to step B05.

In step B05, a light-emitting layer and second electrodes are sequentially formed on the first inorganic pixel definition layer p1 and the second inorganic pixel definition layer p2. The second electrode is an anode or a cathode. In embodiments of the present disclosure, the second electrode is a cathode.

Optionally, the light-emitting layer may be formed by ink-jet printing or evaporation.

Thus, the preparation process of the display panel in the embodiments of the present invention is completed.

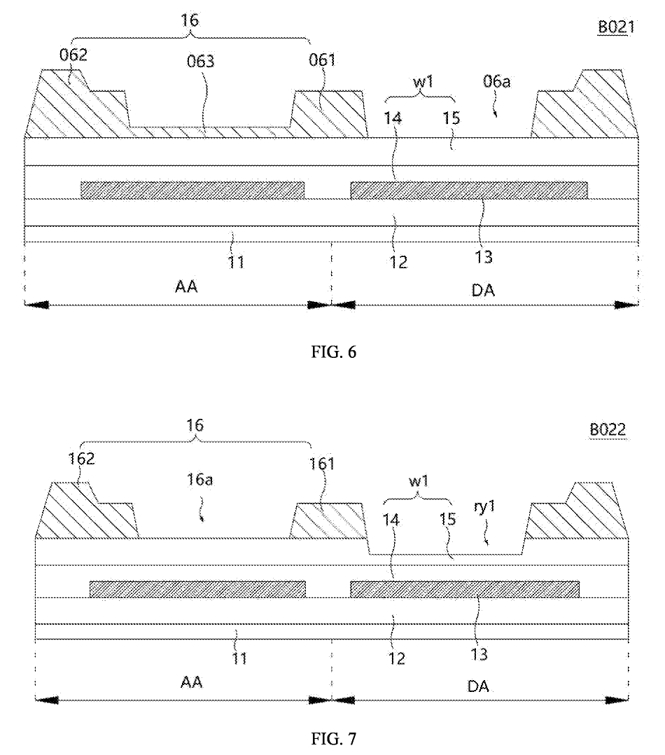

Optionally, in some embodiments of the present disclosure, reference is made to FIGS. 6 to 9. In FIGS. 6 to 9, the method of preparing the display panel in embodiments of the present disclosure employing one photomask not only includes the preparation process steps in the embodiments corresponding to FIGS. 2 to 5, but also includes a step of forming redundant openings 15b penetrating through at least a part of the first electrode 13 in the pixel redundancy area DA.

Optionally, step B02 includes steps as follows.

Referring to FIG. 6, in step B021, a first pattern of the photoresist layer 16 is formed on the side of the second inorganic layer 15 away from the substrate 11. The first pattern of the photoresist layer 16 includes a first initial photoresist strip 061, a second initial photoresist strip 062, and a third initial photoresist portion 063. The first pattern of the photoresist layer 16 is further provided with an initial opening 06a exposing the inorganic stacked structure w1. The third initial photoresist portion 063 is located in the display area AA and is connected with the first initial photoresist strip 061 and the second initial photoresist strip 062 around it. The initial opening 06a is located in the pixel redundancy area DA, and the first initial photoresist strip 061 and the second initial photoresist strip 062 are disposed around the initial opening 06a. Each of the third initial photoresist portion 063 and the initial opening 06a corresponds to one of the first electrodes 13.

Referring to FIG. 7, in step B022, the first pattern of the photoresist layer is used as a mask, while the inorganic stacked structure w1 is etched, the photoresist layer 16 is subjected to ashing and the third initial photoresist portion 063 is removed, so as to form a second pattern of the photoresist layer 16. The second pattern of the photoresist layer 16 includes a first photoresist strip 161 and a second photoresist strip 162. The first photoresist strip 161 and the second photoresist strip 162 are cross-connected to form a plurality of openings 16a. The thickness of the first photoresist strip 161 is less than the thickness of the second photoresist strip 162. In the display area AA, one opening 16a is provided corresponding to one first electrode 13. The pattern of the opening 16a in a top view is within the area of the first electrode 13. In the pixel redundancy area DA, the inorganic stacking structure w1 is formed with redundant recessed grooves ry1 in areas corresponding to the initial openings 06a.

Then, moving to step B03.

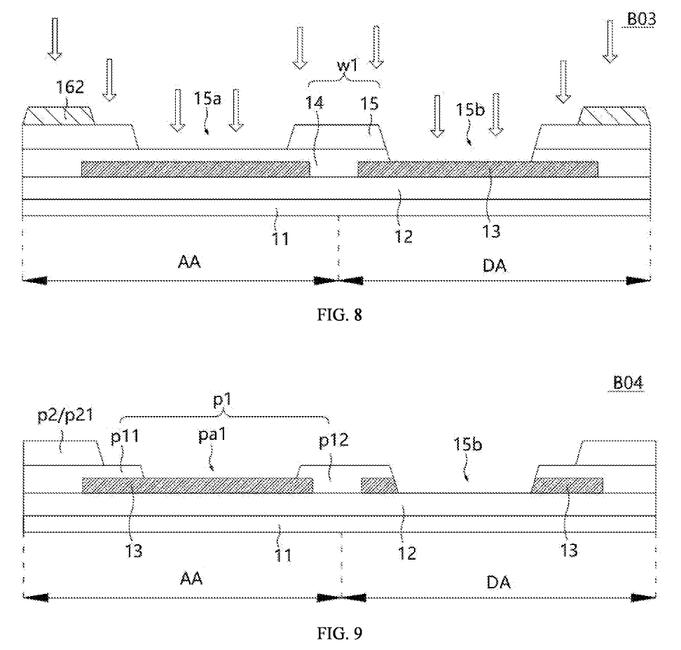

Referring to FIG. 8, in step B03, the step of ashing the photoresist layer 16 while etching the inorganic stacked structure w1 by using the photoresist layer 16 as a mask further includes: forming a redundant opening 15b exposing the first electrodes in an area of the inorganic stacked structure w1 corresponding to the redundant recessed groove ry1 in the pixel redundancy area DA.

Then, moving to step B04.

Referring to FIG. 9, in step B04, the step of etching the inorganic stacked structure w1 by using the thinned second photoresist strips 162 as a mask while ashing to remove the second photoresist strips 162 further includes extending the redundant opening 15b in a direction towarding the first electrodes 13 to penetrate through at least a part of each of the plurality of first electrodes 13 in the pixel redundancy area DA.

Optionally, the redundant opening 15b may penetrate through a part of the first electrode 13, or may completely penetrate through the first electrode 13 to provide more ink solvent.

It should be noted that the method of preparing the display panel corresponding to FIGS. 6 to 9 includes all steps of the method of preparing the display panel in the embodiments corresponding to FIGS. 1 to 5. Here, FIGS. 1 to 5 may correspond to the preparation process of the display area AA of the display panel.

It can be understood that in the steps of the preparation method showing in FIGS. 6 to 9, one photomask is used in embodiments of the present disclosure to form a patterned photoresist layer 16. The photoresist layer 16 is used as a mask to form a patterned first inorganic pixel definition layer p1 and a patterned second inorganic pixel definition layer p2. Here, a pixel opening pa1 is formed in the display area AA, and a redundant opening 15b penetrating through at least a part of the first electrode 13 is formed in the pixel redundancy area DA to deepen the depth of the redundant opening 15b. Moreover, the embodiments of the present disclosure can also reduce the effect of thermal process on the thin film transistor, thereby reducing the risk of negative bias of the thin film transistor and the number of the used photomasks.

Secondly, since the redundant opening 15b penetrates through at least a part of the first electrode 13, the depth of the redundant opening 15b is deepened to increase the volume of the redundant opening 15b, so that the redundant opening 15b can contain more ink of the light-emitting layer material. When the printed ink is heated, the pixel redundancy area DA containing more ink has more solvents, which can improve the saturated vapor pressure of the edge area to balance the overall drying atmosphere, thereby improving the thickness uniformity of the light-emitting layer.

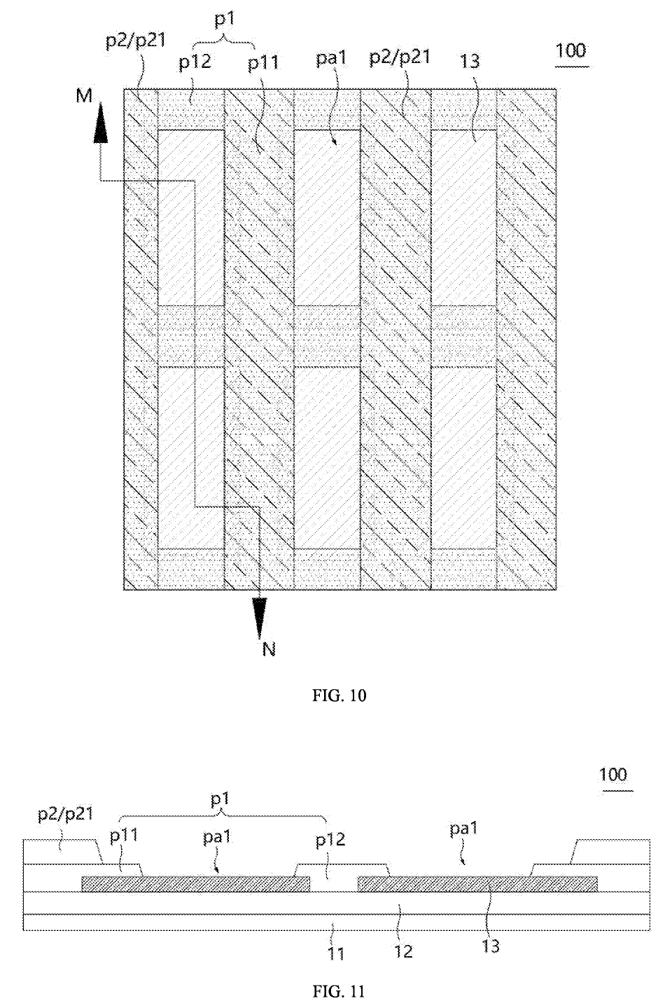

Referring to FIGS. 10 and 11, embodiments of the present disclosure further provide a display panel 100, which includes a substrate 11, a thin film transistor structure layer 12, a plurality of first electrodes 13, a first inorganic pixel definition layer p1, and a second inorganic pixel definition layer p2.

The thin film transistor structure layer 12 is disposed on the substrate 11. The thin film transistor structure layer 12 includes thin film transistors. The plurality of first electrodes 13 are disposed on the side of the thin film transistor structure layer 12 away from the substrate 11.

The first inorganic pixel definition layer pl is disposed on the side of the thin film transistor structure layer 12 away from the substrate 11. The first inorganic pixel definition layer p1 includes a plurality of first pixel definition portions p11 and a plurality of second pixel definition portions p12. The first pixel definition portions p11 and the second pixel definition portions p12 are cross-connected to form a plurality of pixel openings pa1 exposing the first electrodes 13.

The second inorganic pixel definition layer p2 is disposed on one side of the first inorganic pixel definition layer pl away from the substrate 11. The second inorganic pixel definition layer p2 includes a plurality of third pixel definition portions p21. The extension direction of the third pixel definition portions p21 are consistent with the extension direction of the first pixel definition portions p11. Each third pixel defining portion p21 is correspondingly disposed on one side of the first pixel defining portion p11 away from the substrate 11.

It should be noted that the display panel 100 according to the embodiments of the present disclosure is prepared by the method of preparing the display panel according to any one of the above-mentioned embodiments.

Optionally, the extension direction of the first pixel defining section p11 is perpendicular to the extension direction of the second pixel defining section p12. However, it is not limited to this. For example, they may also intersect non-perpendicularly.

The display panel 100 according to the embodiments of the present disclosure adopts the first inorganic pixel definition layer p1 and the second inorganic pixel definition layer p2. Compared with the organic pixel definition layer, embodiments of the present disclosure can reduce the influence of the thermal process of the organic pixel definition layer on the thin film transistor, thereby reducing the risk of negative bias of the thin film transistor and the number of the used photomasks.

Optionally, in some embodiments of the present disclosure, the thickness of the third pixel definition portion p21 is greater than the thickness of the first inorganic pixel definition layer p1.

The third pixel definition portions p21 are disposed on the first inorganic pixel definition layer p1. The extension direction of the third pixel definition portions p21 is consistent with the extension direction of the first pixel definition portions p11, so that the third pixel definition portions p21 are disposed at intervals in the extension direction of the second pixel definition portions p12. Two adjacent third pixel defining portions p21 define a pixel column in which light-emitting materials of the same color can be printed. The arrangement of the third pixel defining portions p21 can avoid mixing of inks in adjacent pixel columns.

Optionally, the thickness of the first inorganic pixel definition layer p1 is between 1000 angstroms and 5500 angstroms. For example, it can be 1000 angstroms, 1500 angstroms, 2000 angstroms, 2500 angstroms, 3000 angstroms, 3500 angstroms, 4000 angstroms, 4500 angstroms, 5000 angstroms or 5500 angstroms. The thickness of the second inorganic pixel defining layer p2 is between 5000 angstroms and 15000 angstroms. For example, it can be 5000 angstroms, 5500 angstroms, 6000 angstroms, 6500 angstroms, 7000 angstroms, 7500 angstroms, 8000 angstroms, 8500 angstroms, 9000 angstroms, 9500 angstroms, 10000 angstroms, 10500 angstroms, 11,000 angstroms, 11500 angstroms, 12,000 angstroms, 12500 angstroms, 13,000 angstroms, 13500 angstroms, 14,000 angstroms, 14500 angstroms, or 15,000 angstroms.

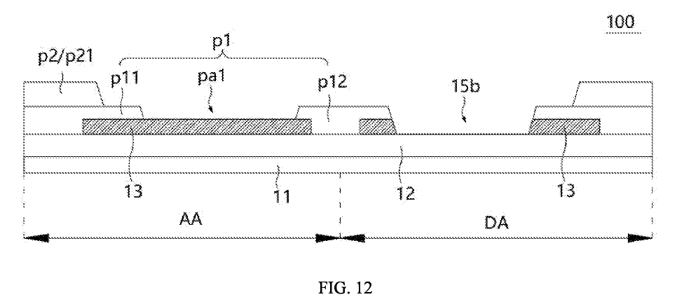

Referring to FIG. 12, FIG. 12 is another schematic structural diagram of a display panel 100 according to embodiments of the present disclosure. FIG. 12 will describe the parts of the display panel 100 that are different from any of the above embodiments to avoid redundant description. The structure of the display area AA of the display panel 100 is similar to or the same as the structure of the display panel 100 corresponding to FIGS. 10 to 11. Therefore, details are not described herein.

In FIG. 12, in some embodiments of the present disclosure, the display panel 100 includes a display area AA and a pixel redundancy area DA disposed on at least one side of the display area AA. The first inorganic pixel definition layer p1 and the second inorganic pixel definition layer p2 are disposed in the display area AA and the pixel redundancy area DA. The pixel openings pa1 are disposed in the display area AA. The first inorganic pixel defining layer p1 is further provided with redundant openings 15b, and the redundant openings 15b are disposed in the pixel redundancy area DA and completely penetrate through at least a part of each first electrode 13.

Optionally, the redundant opening 15b may penetrate through a part of the first electrode 13, or may completely penetrate through the first electrode 13 to provide more ink solvent.

Here, since the redundant opening 15b penetrates through at least a part of the first electrode 13, the depth of the redundant opening 15b is deepened to increase the volume of the redundant opening 15b, so that the redundant opening 15b can contain more ink of the light-emitting layer material. When the printed ink is heated, the pixel redundancy area DA containing more ink has more solvents, which can improve the saturated vapor pressure of the edge area to balance the overall drying atmosphere, thereby improving the thickness uniformity of the light-emitting layer.

In view of the foregoing, the display panel and preparation method thereof provided in embodiments of the present disclosure have been described in detail above, and the principles and embodiments of the present disclosure are described by using specific examples herein. Descriptions of the above embodiments are merely intended to help understand the technical solutions and core ideas of the present disclosure. Meanwhile, for those skilled in the art, based on the idea of the present disclosure, there will be changes in the specific implementation and the scope of application. Accordingly, the content of this specification should not be construed as a limitation on the present disclosure.

What is claimed is:

1. A method of preparing a display panel, comprising:
forming a thin film transistor structure layer, a plurality of first electrodes, a first inorganic layer, and a second inorganic layer sequentially on a substrate, and the first inorganic layer and the second inorganic layer being stacked to form an inorganic stacked structure;
forming a patterned photoresist layer on one side of the second inorganic layer away from the substrate; the photoresist layer comprising a plurality of first photoresist strips and a plurality of second photoresist strips, the plurality of first photoresist strips and the plurality of second photoresist strips being cross-connected to form a plurality of openings, a thickness of each of the plurality of first photoresist strips being less than a thickness of each of the plurality of second photoresist strips, each of the plurality of openings being disposed corresponding to each of the plurality of first electrodes, and a pattern of each of the plurality of openings in a top view being within an area of each of the plurality of first electrodes;
etching the inorganic stacked structure by using the photoresist layer as a mask; and ashing the photoresist layer to remove the plurality of first photoresist strips, thin the plurality of second photoresist strips, and form a plurality of grooves on one side of the inorganic stacked structure away from the substrate; and
etching the inorganic stacked structure by using the thinned plurality of second photoresist strips as a mask while ashing to remove the plurality of second photoresist strips, so that the inorganic stacked structure forms a stacked first inorganic pixel definition layer and a second inorganic pixel definition layer, the first inorganic pixel definition layer comprising a plurality of first pixel definition portions and a plurality of second pixel definition portions, and the plurality of first pixel definition portions and the plurality of second pixel definition portions being cross-connected to form a plurality of pixel openings exposing the plurality of first electrodes; the second inorganic pixel definition layer comprising a plurality of third pixel definition portions, an extension direction of the plurality of third pixel definition portions being consistent with an extension direction of the plurality of first pixel definition portions, and each of the plurality of third pixel definition portions being correspondingly disposed on one side of each of the plurality of first pixel definition portions away from the substrate.

2. The method according to claim 1, wherein said “etching the inorganic stacked structure by using the thinned plurality of second photoresist strips as a mask while ashing to remove the plurality of second photoresist strips” comprises:
etching the inorganic stack structure, so that the plurality of pixel openings exposing the plurality of first electrodes are formed in areas of the inorganic stack structure corresponding to the plurality of grooves, the second inorganic layer being removed and the first inorganic layer being remained in areas of the inorganic stack structure corresponding to the plurality of first photoresist strips, and both the first inorganic layer and the second inorganic layer being remained in areas of the inorganic stack structure corresponding to the plurality of second photoresist strips; and the patterned first inorganic layer forming a first inorganic pixel definition layer and the patterned second inorganic layer forming a second inorganic pixel definition layer.

3. The method according to claim 2, wherein a rate of etching the inorganic stacked structure in said “etching the inorganic stacked structure by using the photoresist layer as a mask; and ashing the photoresist layer” is a first rate; and
a rate of etching the inorganic stacked structure in said “etching the inorganic stacked structure by using the thinned plurality of second photoresist strips as a mask while ashing to remove the plurality of second photoresist strips” is a second rate;
wherein the second rate is less than the first rate.

4. The method according to claim 3, wherein the thickness of each of the plurality of first photoresist strips is between 2/3 and 4/5 of the thickness of each of the plurality of second photoresist strips; and
in said “etching the inorganic stacked structure by using the photoresist layer as a mask; and ashing the photoresist layer”, a thickness ratio of each of the plurality of first photoresist strips to the second inorganic layer is equal to an etching selectivity ratio of each of the plurality of first photoresist strips to the second inorganic layer.

5. The method according to claim 4, wherein in said “etching the inorganic stacked structure by using the thinned plurality of second photoresist strips as a mask while ashing to remove the plurality of second photoresist strips”, a thickness of each of the thinned plurality of second photoresist strips is less than or equal to a thickness of the first inorganic layer, and a rate of etching each of the plurality of second photoresist strips is less than a rate of etching the first inorganic layer.

6. The method according to claim 1, wherein in said “forming a patterned photoresist layer”, a drying temperature of the photoresist layer is between 60 °C and 150 °C, and a drying time of the photoresist layer is less than 25 minutes.

7. The method according to claim 1, wherein said “forming a patterned photoresist layer on one side of the second inorganic layer away from the substrate” comprises:
forming a first pattern of the photoresist layer on one side of the second inorganic layer away from the substrate; the first pattern of the photoresist layer comprising a first initial photoresist strip, a second initial photoresist strip and a third initial photoresist portion, the first pattern of the photoresist layer being further provided with an initial opening exposing the inorganic stacked structure, the third initial photoresist portion being located in a display area and being connected with the first initial photoresist strip and the second initial photoresist strip around it, the initial opening being located in a pixel redundancy area and the first initial photoresist strip and the second initial photoresist strip being disposed around the initial opening, and each of the third initial photoresist portion and the initial opening respectively corresponding to one of the plurality of first electrodes;
forming a second pattern of the photoresist layer by ashing the first pattern of the photoresist layer and removing the third initial photoresist portion while etching the inorganic stacked structure by using the first pattern of the photoresist layer as a mask; the second pattern of the photoresist layer comprising a plurality of first photoresist strips and a plurality of second photoresist strips, the plurality of first photoresist strips and the plurality of second photoresist strips being cross-connected to form a plurality of openings, a thickness of each of the plurality of first photoresist strips being less than a thickness of each of the plurality of second photoresist strips; in the display area, each of the plurality of openings corresponding to each of the plurality of first electrodes, the pattern of each of the plurality of openings in a top view being within the area of each of the plurality of first electrodes; and in the pixel redundancy area, the inorganic stacked structure being formed with a redundant recessed groove in an area corresponding to the initial opening;
said “etching the inorganic stacked structure by using the photoresist layer as a mask; and ashing the photoresist layer” further comprises forming a redundant opening exposing the plurality of first electrodes in an area of the inorganic stacked structure corresponding to the redundant recessed groove in the pixel redundancy area; and
said “etching the inorganic stacked structure by using the thinned plurality of second photoresist strips as a mask while ashing to remove the plurality of second photoresist strips” further comprises extending the redundant opening in a direction towarding the plurality of first electrodes to penetrate through at least a part of each of the plurality of first electrodes in the pixel redundancy area.

8. The method according to claim 1, wherein the substrate is a flexible substrate or a hard substrate, a material of the substrate is selected from one of glass, sapphire, silicon, silicon dioxide, polyethylene, polypropylene, polystyrene, polylactic acid, polyethylene-naphthalate, polyethylene terephthalate, polyethylene naphthalate, polycarbonate, polyethersulfone, aromatic fluorotoluene containing polyarylates, polycyclic olefins, polyimide or polyurethane.

9. The method according to claim 1, wherein the thin film transistor structure layer comprises a thin film transistor, and a channel material of the thin film transistor is a silicon semiconductor or a metal oxide semiconductor.

10. The method according to claim 1, wherein the first inorganic layer and the second inorganic layer are formed by chemical vapor deposition.

11. The method according to claim 1, wherein materials of the first inorganic layer and the second inorganic layer are same or different, and the materials of each of the first inorganic layer and the second inorganic layer are inorganic materials selecting from silicon oxide, silicon nitride, aluminum oxide, or zirconium oxide.

12. The method according to claim 1, wherein a thickness of the first inorganic layer is between 1000 angstroms and 5500 angstroms.

13. The method according to claim 1, wherein a thickness of the second inorganic layer is between 5000 angstroms and 15000 angstroms.

14. The method according to claim 1, wherein the thickness of the second inorganic layer is greater than the thickness of the first inorganic layer.

15. The method according to claim 1, wherein in said “ashing the photoresist layer”, a temperature of the ambient temperature is between 15 °C and 35 °C.

16. The method according to claim 1, wherein an etching gas is selected from a fluorine-based gas, a chlorine-based gas, or an inert gas.

17. The method according to claim 16, wherein the fluorine-based gas is carbon tetrafluoride, trifluoromethane, or sulfur hexafluoride.

18. A display panel, comprising:
a substrate;
a thin film transistor structure layer disposed on the substrate, the thin film transistor structure layer comprising a thin film transistor;
a plurality of first electrodes disposed on one side of the thin film transistor structure layer away from the substrate;
a first inorganic pixel definition layer disposed on one side of the thin film transistor structure layer away from the substrate, the first inorganic pixel definition layer comprising a plurality of first pixel definition portions and a plurality of second pixel definition portions, and the plurality of first pixel definition portions and the plurality of second pixel definition portions being cross-connected to form a plurality of pixel openings exposing the plurality of first electrodes; and
a second inorganic pixel definition layer disposed on one side of the first inorganic pixel definition layer away from the substrate, the second inorganic pixel definition layer comprising a plurality of third pixel definition portions, an extension direction of the plurality of third pixel definition portions being consistent with an extension direction of the plurality of first pixel definition portions, and each of the plurality of third pixel definition portions being correspondingly disposed on one side of each of the plurality of first pixel definition portions away from the substrate.

19. The display panel according to claim 18, wherein a thickness of each of the plurality of third pixel defining portions is greater than a thickness of the first inorganic pixel defining layer.

20. The display panel according to claim 18, wherein the display panel comprises a display area and a pixel redundancy area disposed on at least one side of the display area, and the first inorganic pixel definition layer and the second inorganic pixel definition layer are disposed in the display area and the pixel redundancy area; the plurality of pixel openings are disposed in the display area, the first inorganic pixel defining layer is further provided with a redundant opening, and the redundant opening is disposed in the pixel redundancy area and penetrates through at least a part of each of the plurality of first electrodes.
